(19) United States
(12) Patent Application Publication
(10) Pub. No.: US 2004/0006724 A1
(43) Pub. Date: Jan. 8, 2004

(54) Network processor performance monitoring system and method

(75) Inventors: Sridhar Lakshmanamurthy, Sunnyvale, CA (US); Mark B. Rosenbluth, Uxbridge, MA (US); Jeen-Yuan Miin, Palo Alto, CA (US)

Correspondence Address: KENYON & KENYON, 1500 K STREET, N.W., SUITE 700, WASHINGTON, DC, 20005, US

(73) Assignee: Intel Corporation

(21) Appl. No.: 10/189,239

(22) Filed: Jul. 5, 2002

(51) Int. Cl. G06F 9/44; H03K 19/003; H05K 10/00; H02H 3/05; H04B 1/74; H04L 1/22

(52) U.S. Cl. 714/25

(57) ABSTRACT

Embodiments described herein provide a system and method that advantageously reduces the number of internal signals required to monitor the performance of a network processor. A plurality of events may be selected from a predetermined number of design unit events, and a plurality of signals may be selected from a predetermined number of design unit signals. A plurality of counters may be associated with the plurality of signals, and for each of the plurality of signals, a number of event occurrences may be counted and sent to a processor unit.

### TECHNICAL FIELD

This disclosure relates to processor architectures. More specifically, this disclosure relates to a system and method for monitoring the performance of a network processor.

### BACKGROUND OF THE INVENTION

Current network processors designed for network access or edge applications operate at very fast speeds, typically commensurate with SONET OC-48 or greater (Synchronous Optical Network (SONET), ANSI Standard T1.105-2001, published 2001; Optical Carrier Level 48). SONET defines a modular family of rates and formats available for use in network interfaces, including various optical carrier levels and associated line transfer rates, such as, for example, OC-48 defining a line transfer rate of 2.488 Gbps (Gigabits per second) and OC-192 defining a line transfer rate of 9.952 Gbps. In order to support data processing and transfer speeds of this magnitude, network processors may include many different components optimally designed to support very high-speed network traffic. Generally, a network processor may be envisioned as a plurality of functional design units interconnected by one or more internal buses. Each network processor design unit may include hardware components, firmware, and/or software to provide the desired functionality, such as, for example, data input and output, data processing, data storage, etc. Additionally, the design units may operate at different frequencies, depending upon each design unit's functionality and internal or external interface requirements. Consequently, a typical network processor may contain a multitude of internal functional design units, operating at dissimilar. frequencies, the successful coordination of which requires painstaking, and time-consuming, processing and data flow simulation and abalyses.

Generally, traditional performance data acquisition requires the instrumentation of internal processor components using software telemetry messages, or hardware telemetry signals, tied to specific internal component events. For a network processor, software monitoring may unavoidably alter the performance of the specific design unit under examination, and, generally, may not provide adequate monitoring resolution, frequency or inter-unit concurrency. Network processor internal bus bandwidth limitations may also preclude significant software-based monitoring efforts. Hardware event signals may impact network processor design unit performance to a lesser degree, but may require a significant investment in hardware, as well as additional network processor resources, to monitor the vast number of signals required, e.g., one signal/counter pair for each design unit event under inspection. Successful network processor performance analysis and optimization may require well over a hundred ivents to be monitored for each design unit, leading to hundreds, if not thousands, of individual hardware signals and counters that must be routed within the network processor, counted, and tramsferred to a central processor or external data interface. Moreover, various network processor design units may operate at different internal clock frequencies, imposing additional complexity to the performance data aquisition problem.

### BRIEF DESCRIPTION OF THE DRAWINGS

FIG. 1 depicts a network processor block diagram, according to an embodiment of the present invention.

FIG. 2 depicts a design unit block diagram, according to an embodiment of the present invention.

FIG. 3 depicts a state diagram, according to an embodiment of the present invention.

FIG. 4 depicts a performance monitoring unit block diagram, according to an embodiment of the present invention.

FIG. 5 illustrates a method for monitoring the performance of a network processor, according to an embodiment of the present invention.

### DETAILED DESCRIPTION

Embodiments described herein provide a system and method that advantageously reduces the number of internal signals required to monitor the performance of a network processor. A plurality of events may be selected from a predetermined number of design unit events, and a plurality of signals may be selected from a predetermined number of design unit signals. A plurality of counters may be associated with the plurality of signals, and for each of the plurality of signals, a number of event occurrences may be counted and sent to a processor unit.

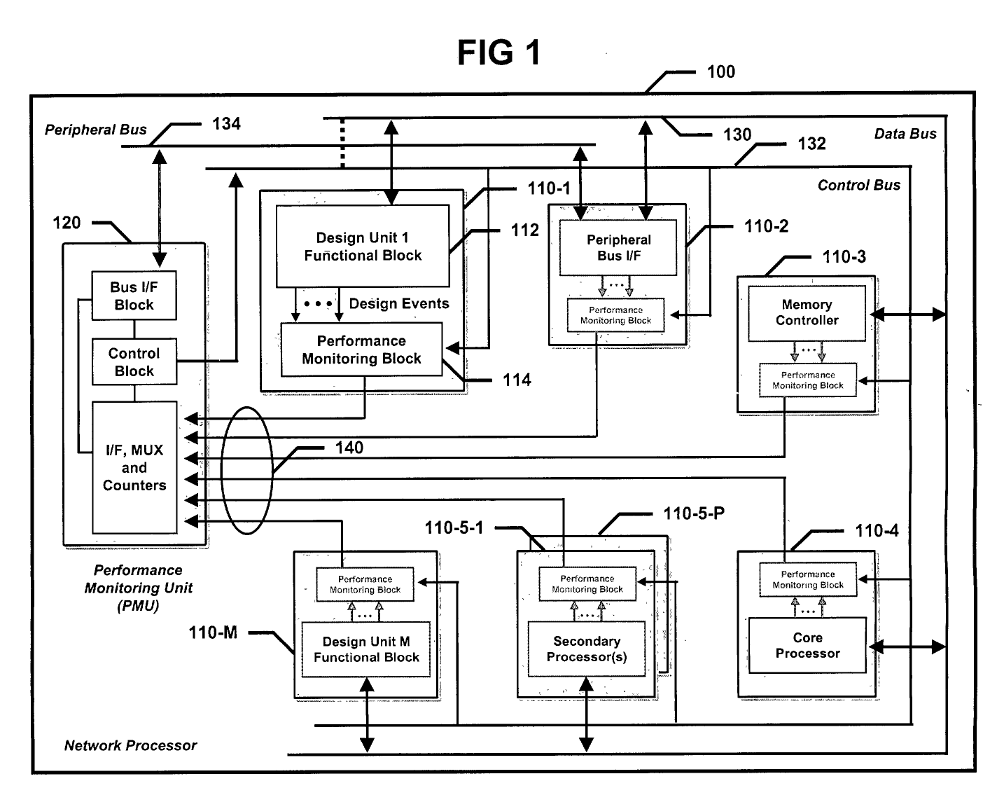

Referring to the network processor block diagram depicted in FIG. 1, in an embodiment, network processor 100 may include a plurality of design units 110-1 . . . 110-M, each configured to perform some measure of functionality within network processor 100. For example, design unit 110-1 may be a media switch fabric (MSF) interface to connect network processor 100 to a physical layer device and/or a switch fabric interface. Or, design unit 110-1 may be a Peripheral Component Interconnect (PCI) interface to connect network processor 100 to PCI peripheral components (PCI Local Bus Specification, Version 2.3, published March 2002). The total number of design units M may depend upon the apportionment and granularity of network processor functionality, but, in an embodiment, M may include up to 32 design units.

Several exemplary design units are depicted, including peripheral bus interface 110-2 (which may also include scratchpad memory and a hash unit), memory controller 110-3 coupled to external memory, such as, for example, static random access memory (SRAM) or dynamic random access memory (DRAM) (not shown for clarity), core processor 110-4 and secondary processors 110-5-1 to 110-5-P. Multiple instances of these design units, as well as other design unit types, are clearly possible and are explicitly contemplated by this disclosure. Generally, network processor 100 may be especially useful for tasks that can be divided into parallel subtasks or functions, such as network data packet processing.

Each of design units 110-1 . . . 110-M may be coupled to at least one internal bus, such as, for example, data bus 130. Additional buses may also be included within network processor 100 and coupled to the plurality of design units 110-1 . . . 110-M, such as, for example, control bus 132 and peripheral bus 134. In one embodiment, peripheral bus 134 may be an Advanced Peripheral Bus (APB), as defined by the Advanced Microcontroller Bus Architecture (AMBA) Specification Rev 2.0, published May 1999. In an embodiment, data bus 130 may include two independent, unidirectional buses, or push-pull buses, to move data from external memory, through memory controller 110-3, to design units 110-1 . . . 110-M, and to move data from design units 110-1 . . . 110-M, through memory controller 110-3, to external memory (respectively). A command bus may also be included within network processor 100 and may be coupled to design units 110-1 . . . 110-M (although not shown for clarity). Alternatively, data bus 130, control bus 132 and peripheral bus 134 may be coupled together as a single processor bus, depicted by bridge 136.

Core processor 110-4 may support various processing tasks, such as, for example, high-performance processing of complex algorithms, route table maintenance and system-level management functions, including performance monitoring. In an embodiment, core processor 110-4 may be an embedded 32-bit RISC (reduced instruction set computer) core processor, such as, for example, an Intel® XSCALE™ core manufactured by Intel Corporation of Santa Clara, Calif. Core processor 110-4 may also include an operating system (OS), such as, for example, VxWorks® manufactured by Wind River Systems Inc. of Alameda, Calif., etc.

Secondary processors 110-5-1 . . . 110-5-P may support hardware-based, multi-threaded data processing, such as, for example, network data packet processing. In an embodiment, secondary processors 110-5-1 . . . 110-5-P may include programmable multi-threaded RISC processors, such as, for example, Intel® microengine (ME) processors. Secondary processors 110-5-1 . . . 110-5-P may be logically and/or physically organized as two or more equal groups, or clusters, and may be coupled together, in sequential order, via a plurality of next neighbor buses. The total number of secondary processors P may depend upon the desired data throughput processing capability of network processor 100, but, generally, P may be a multiple of two, i.e., e.g., four, eight, 16, etc.

Network processor 100 may also include a performance monitoring unit 120 coupled to control bus 132, peripheral bus 134 and the plurality of design units 110-1 . . . 110-M. Generally, performance monitoring unit 120 may receive and decode performance monitoring commands from core processor 110-4 and program the appropriate plurality of design units 110-1 . . . 110-M to route the desired events over the plurality of event buses 140 to performance monitoring unit 120. In an embodiment, core processor 110-4 may send performance monitoring commands over data bus 130 to peripheral bus interface 110-2, which may then transfer the performance monitoring commands over peripheral bus 134 to performance monitoring unit 120. Similarly, performance monitoring unit 120 may send performance monitoring data over peripheral bus 134 to peripheral bus interface 110-2, which may then transfer the performance monitoring data to core processor 110-4 over data bus 130. Alternatively, performance monitoring unit 120 may be coupled directly to data bus 130, in which case core processor 110-4 may send performance monitoring commands to, and receive performance monitoring data from, performance monitoring unit 120 directly over data bus 130.

Each of the plurality of design units 110-1 . . . 110-M may include functional block 112 and performance monitoring block 114. Functional block 112 may include various resources adapted to implement the desired functionality of each of the plurality of design units 110-1 . . . 110-M, such as, for example, logic circuits, general purpose registers, memory buffers, first-in-first-out (FIFO) queues, finite state machines, application specific integrated circuits (ASICs), processor(s), firmware, local memory, etc. Functional block 112 may be coupled to both internal and external devices, including, for example, data bus 130, an external network or switch fabric (not shown), etc. Functional block 112 may also include appropriate hardware, firmware and/or software to monitor various design unit events and provide indications of the occurrences of these event to performance monitoring block 114. Performance monitoring block 114 may include appropriate hardware, firmware and/or software to receive these events and output N event signals, over N event buses, to performance monitoring unit 120. For each of the plurality of design units 110-1 . . . 110-M, N event signals may be provided to performance monitoring unit 120 over N event buses. Accordingly, a plurality of event buses 140 may be input to performance monitoring unit 120, generally consisting of N event buses for each of the plurality of design units 110-1 . . . 110-M. Advantageously, each of the plurality design units 110-1 . . . 110-M may include a specific set of performance monitoring events encompassing the necessary metrics to ensure optimum operation of each design unit.

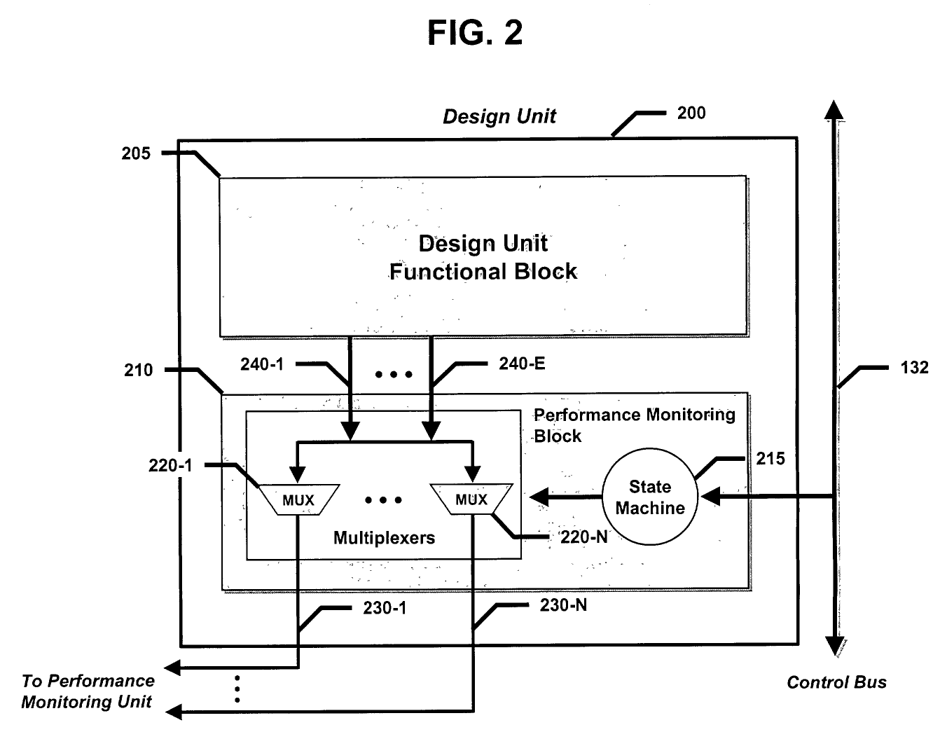

Referring to the design unit block diagram of FIG. 2, in an embodiment, generic design unit 200 may include design functional block 205 and performance monitor block 210, corresponding to functional block 112 and performance monitoring block 114 of design unit 110-1 depicted in FIG. 1. Performance monitor block 210 may include state machine 215 coupled to control bus 132, and a plurality of event multiplexers 220-1 . . . 220-N coupled to functional block 205 and state machine 215. The plurality of event multiplexers 220-1 . . . 220-N may be coupled to performance monitoring unit 120 via a plurality of event buses 230-1 . . . 230-N. Accordingly, each of the plurality of event multiplexers 220-1 . . . 220-N may be associated with one of the plurality of event buses 230-1 . . . 230-N.

For example, in one embodiment, design unit 200 may provide an interface to a media switch fabric (MSF). In this embodiment, functional block 205 may include a receive buffer, a transmit buffer, a thread freelist queue, a status buffer, a state machine including at least one logic unit, as well as other components. According to the specific implementation of the MSF interface for any particular switch fabric or network, various events associated with MSF interface performance may be identified and monitored. For example, the thread freelist queue may include a list of available processing threads associated with the plurality of secondary processors 110-5-1 . . . 110-5-P. Various performance monitoring events may be associated with the thread freelist queue, such as, for example, a thread freelist en-queue event, a thread freelist de-queue event, a thread freelist full event, a thread freelist not empty event, etc. Each of these thread freelist events may be monitored by appropriate hardware, firmware and/or software within functional block 205 and communicated to performance monitor block 210 via a plurality of event signals 240-1 . . . 240-E, which may be, for example, transistor-to-transistor logic (TTL) signals, etc. Event signal timing may be coordinated across network processor 100 by the use of a system or bus clock signal available to each of the plurality of design units 110-1 . . . 110-M, such as, for example, data bus 130, control bus 132, etc. For those design units operating at a higher frequency than data bus 130, for example, design unit functional block 205 may include the appropriate hardware, firmware, and/or software to coordinate performance monitoring event acquisition and signal transfer between functional block 205, operating at the higher, internal clock frequency of design unit 200, and event timing signals, propagating at the lower bus clock frequency of data bus 130.

In an embodiment, performance monitoring unit 120 may generate control cycles on control bus 132 to program each performance monitoring block 114 within the plurality of design units 110-1 . . . 110-M. For example, state machine 215 may monitor control bus 132 and decode control cycles generated by performance monitoring unit 120. Several different types of control cycles may be generated, such as, for example, RESET cycles, INIT cycles, CONFIG cycles, etc. Each control cycle may include various types of information, including, for example, a design unit number, a design event number, a multiplexer number, etc. In response to the control cycles, state machine 215 may generate various select and control signals for the plurality of event multiplexers 220-1 . . . 220-N.

Each of the plurality of event multiplexers 220-1 . . . 220-N may route a design event signal, selected from the plurality of design event signals 240-1 . . . 240-E, from functional block 205 to performance monitoring unit 120 over one of the plurality of event buses 230-1 . . . 230-N. Accordingly, in an embodiment, each of the plurality of event multiplexers 220-1 . . . 220-N may include one output coupled to one of the plurality of event buses 230-1 . . . 230-N, as well as up to E inputs coupled to design functional block 205. In an embodiment, E may be as large as 128 and N may be as small as six, i.e., up to six event signals may be selected from as many as 128 design unit event signals and routed from design functional block 205 to performance monitoring unit 120. Of course, both E and N may be larger, or smaller, depending upon various network processor design factors, including, for example, overall design complexity, specific implementation considerations, total number of design units, available silicon real estate, etc.

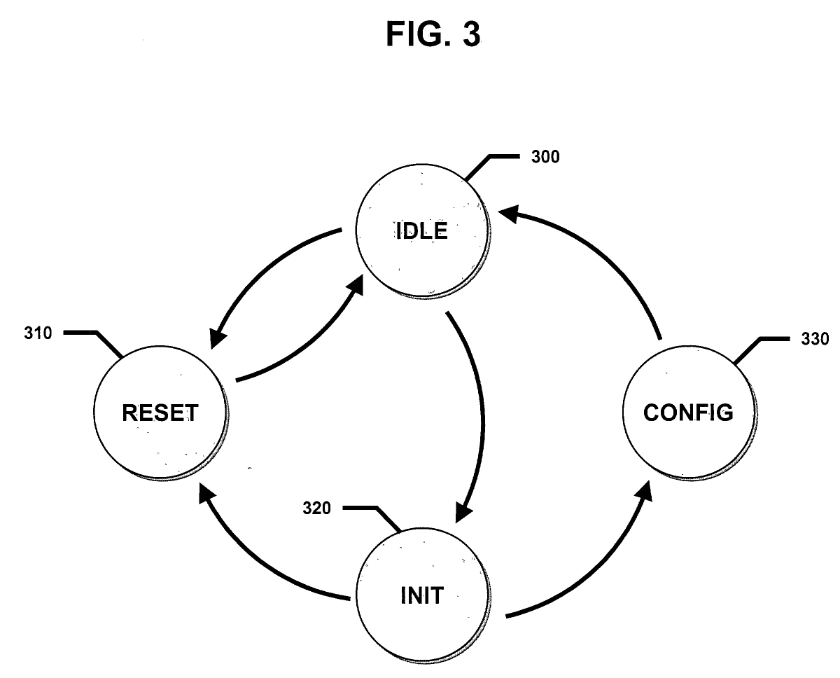

Referring to the state diagram depicted in FIG. 3, in an embodiment, state machine 215 may monitor control bus 132 for a RESET or INIT cycle while in an IDLE state (300). If a RESET cycle is detected, state machine 215 may transition to RESET state (310). While in RESET state (310), state machine 215 may decode the design unit number on control bus 132 and determine whether the decoded design unit number matches a predetermined design unit number associated with state machine 215. For example, design unit 200 may have a design unit number of “1. ” If a match is not determined, then state machine 215 may transition back to IDLE state (300). If a match is determined, state machine 215 may decode the multiplexer number on control bus 132, clear the multiplexer select signal associated with the decoded multiplexer number, and then transition back to IDLE state (300). For example, if the multiplexer number on control bus 132 is decoded as “1,” then the select signal to the first multiplexer, i.e., event multiplexer 220-1, may be cleared. The select signal to the first multiplexer may be cleared, for example, by writing a value to a multiplexer select register.

If an INIT cycle is detected while in IDLE state (300), state machine 215 may transition to INIT state (320). While in INIT state (320), state machine 215 may decode the design unit number on control bus 132 and determine whether the design unit number matches the predetermined design unit number associated with state machine 215. If a match is not determined, then state machine may transition back to IDLE state (300). If a match is determined, then state machine 215 may decode the multiplexer number on control bus 132 and set the appropriate multiplexer select signal. For example, if the multiplexer number on control bus 132 is decoded as “1,” then the select signal to the first multiplexer, i.e., multiplexer 220-1, may be set. The select signal may be set, for example, by writing a value to a multiplexer select register. State machine 215 may then wait for a CONFIG cycle while in INIT state (320). If, however, a RESET cycle having the correct design unit number is detected on control bus 132 before the CONFIG cycle, state machine may transition to RESET state (310), clear the multiplexer select signal associated with the selected multiplexer number, and then transition back to IDLE state (300).

If a CONFIG cycle is detected while in INIT state (320), state machine 215 may transition to CONFIG state (330). While in CONFIG state (330), state machine 215 may decode the design event number on control bus 132 and write the value to the selected multiplexer to select the appropriate design event input signal. State machine 215 may then transition back to IDLE state (200). For example, if the design event number on control bus 132 is decoded as “16,” then this value may be written to the multiplexer previously selected by state machine 215 while in the INIT state (220), i.e., e.g., event multiplexer 220-1 for an multiplexer number decoded as “1.”

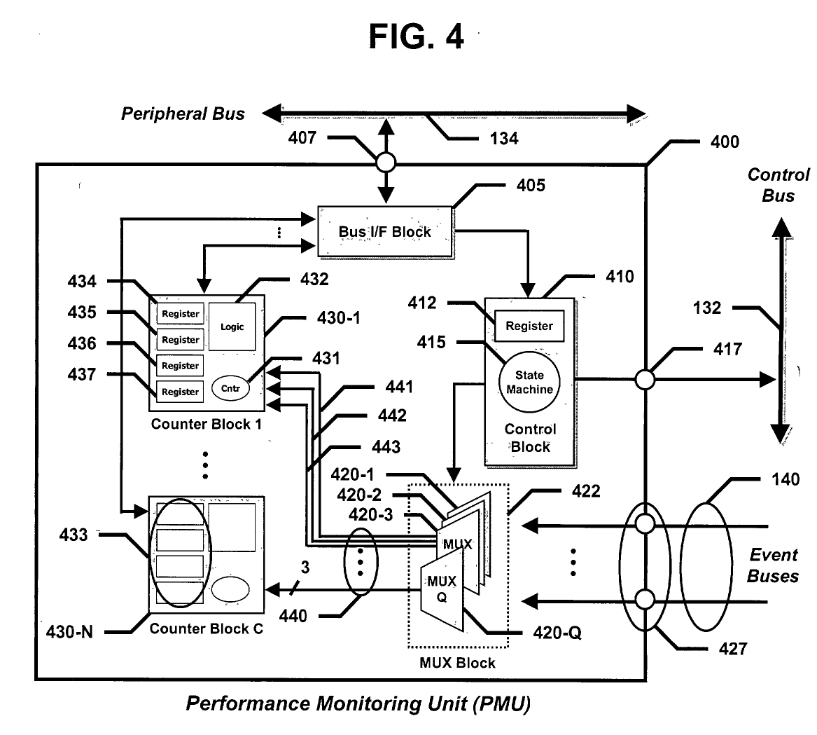

Referring to the performance monitoring unit block diagram of FIG. 4, in an embodiment, performance monitoring unit 400 may include bus interface block 405, bus interface 407, control block 410, control bus interface 417, plurality of event bus multiplexers 420-1 . . . 420-Q, plurality of event bus interfaces 427, and plurality of counter blocks 430-1 . . . 430-C. Bus interface block 405 may be coupled to bus interface 407, control block 410 and plurality of counter blocks 430-1 . . . 430-C. Control block 410 may be coupled to bus interface block 405, control bus interface 417 and plurality of event bus multiplexers 420-1 . . . 420-Q. Each of the plurality of event bus multiplexers 420-1 . . . 420-Q may be coupled to one of the plurality of counter blocks 430-1 . . . 430-C via one of the plurality of event signals 440. Each of the plurality of event bus multiplexers 420-1 . . . 420-Q may also be coupled to each of the plurality of event bus interfaces 427, and accordingly, to each of the plurality of event buses 140, as described above with reference to FIG. 1. In one embodiment, bus interface 405 may generate commands to control block 410, as well as to each of the plurality of counter blocks 430-1 . . . 430-C. In an embodiment, bus interface block 405 may interface to peripheral bus 134, while in an alternative embodiment, bus interface block 405 may interface to data bus 130. Plurality of event bus multiplexers 420-1 . . . 420-Q may be organized as multiplexer block 422.

Generally, each of the plurality of counter blocks 430-1 . . . 430-C may be configured to count design unit events. In an embodiment, each of the plurality of counter blocks 430-1 . . . 430-C may include up/down counter 431, logic 432 and plurality of registers 433. Logic 432 may include, for example, control logic to increment or decrement up/down counter 431 in response to event signals received from at least one of the plurality of bus multiplexers 420-1 . . . 420-Q. The contents of each of the plurality of registers 433 may be read by bus interface block 405 and transferred over bus interface 407. In an embodiment, plurality of registers 433 may include command register 434, event register 435, status register 436 and data register 437. In this embodiment, command register 434, event register 435 and data register 437 may also be written by bus interface block 405.

Plurality of registers 433 may facilitate the counting process for each of the plurality of counter blocks 430-1 . . . 430-C. For example, in response to an event signal received from one of the plurality of event bus multiplexers 420-1 . . . 420-Q, logic 432 may increment up/down counter 431, decrement up/down counter 431, compare a current value in up/down counter 431 and a current value in data register 437 to determine whether a triggering threshold has been met, etc. Additionally, logic 432 may use plurality of registers 433 to store data or commands. For example, in response to a sample command received from bus interface block 405, logic 432 may latch the current value of up/down counter 431 into data register 437 of counter block 430-1. In another example, in response to a data read command received from bus interface block 405, logic 432 may transfer the current value of data register 437 (e.g., within counter block 430-1) to bus interface block 405.

In an embodiment, each of the plurality of event bus multiplexers 420-1 . . . 420-Q may output a specific type of event signal to one of the plurality of counter blocks 430-1 . . . 430-C, such as, for example, an increment event signal, a decrement event signal, a trigger event signal, etc. In an embodiment, plurality of event bus multiplexers 420-1 . . . 420-Q may be arranged within multiplexer block 422 in C sets of three event bus multiplexers (i.e., e.g., Q may be equal to 3*C), with each event bus multiplexer in the set outputting one of three different types of event signals. For example, the first set of three event bus multiplexers may include event bus multiplexers 420-1 . . . 420-3. Accordingly, event bus multiplexer 420-1 may output increment event signal 441 to counter block 430-1, event bus multiplexer 420-2 may output decrement event signal 442 to counter block 430-1, and event bus multiplexer 420-3 may output trigger event signal 443 to counter block 430-1. In this example, logic 432 may increment up/down counter 431 in response to increment event signal 441 and decrement up/down counter 431 in response to decrement event signal 441. Logic 432 may execute a stored opcode or perform a comparison in response to trigger event signal 433. Generally, control block 410 may program each of the plurality of event bus multiplexers 420-1 . . . 420-Q to input the appropriate type of event signal from one of the plurality of event bus interfaces 427. For example, event bus multiplexer 420-1 may be programmed to output increment event signal 441 to counter block 430-1 whenever an increment event signal is received over one of the plurality of event bus interfaces 427, and logic 432 may increment up/down counter 431 each time increment event signal 441 is received from event bus multiplexer 420-1.

Generally, control block 410 may collectively program the various multiplexing elements of network processor 100 to route selected events from plurality of design units 110-1 . . . 110-M to plurality of counter blocks 430-1 . . . 430-C. Control block 410 may receive commands from bus interface block 405, generate multiplexer select signals to program each of the plurality of event bus multiplexers 420-1 . . . 420-Q, and generate various control cycles on control bus 132 to program each performance monitoring block 114 within the plurality of design units 110-1 . . . 110-M, as discussed with reference to FIGS. 2 and 3. In an embodiment, control block 410 may include register 412 and state machine 415. Bus interface block 405 may receive a performance monitoring command, originating from core processor 110-4 or an external interface, over bus interface 407. In an embodiment, the performance monitoring command may include, for example, an event selection code identifying the design unit number and design event number to be monitored, a multiplexer number and a counter block number. Bus interface block 405 may decode the command and write the event selection code, multiplexer number, and counter number to register 412.

State machine 415 may decode the event selection code and multiplexer number contained within register 412 to determine the design unit number, the design unit event and the design unit event multiplexer number. In an embodiment, the event selection code may be a 12-bit number. Bits 0:6 may indicate the design event number and bits 7:11 may indicate the design unit number. For example, for design event number 1 of design unit number 1 (e.g., design unit 110-1), the event code may be represented as 00001000001 (binary). In this example, the multiplexer number may be equal to 1. State machine 415 may assert the proper control cycles, on control bus 132, to program the design unit identified within the event selection code. In an embodiment, the control cycles may include, for example, RESET cycles, INIT cycles, CONFIG cycles, etc., as generally discussed with reference to FIG. 3. State machine 415 may also decode the counter number to determine the proper multiplexer control signals, to assert to one of the plurality of event bus multiplexers 420-1 . . . 420-Q, to route the selected event signal from the plurality of event bus interfaces 427 to one of the plurality of counter blocks 430-1 . . . 430-C. In the example described above, if the counter number equals 1, then the appropriate multiplexer control signal may be asserted to event bus multiplexer 420-1 to route design event number 1 of design unit number 1, from the plurality of event bus interfaces 427 to counter block 430-1.

In an embodiment, each of the plurality of design units 110-1 . . . 110-M may provide six event bus signals to the plurality of event bus interfaces 427 (i.e., e.g., N equals six). In this embodiment, the total number of event buses 140, as well as the total number of event bus interfaces 427, may be 6*M. The event buses provided by each of the plurality of design units 110-1 . . . 110-M may be arranged within the plurality of event buses 140 in sequential order, i.e., e.g., design unit 110-1 may provide the first six event buses within the plurality of event buses 140, etc. Consequently, in the example described above, control unit 410 may decode the event selection code word and the multiplexer number to determine the appropriate multiplexer control signal to provide to event bus multiplexer 420-1 in order to select the first event bus interface within the plurality of event bus interfaces 427.

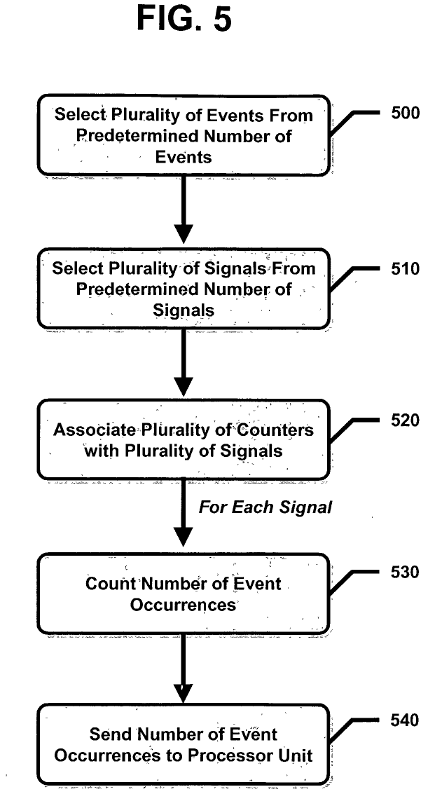

FIG. 5 illustrates a method for monitoring the performance of a network processor, according to an embodiment of the present invention.

A plurality of events may be selected (500) from a predetermined number of design unit events. In an embodiment, core processor 110-4 may select a set of design unit events to be monitored and send the event set to performance monitoring unit 120. The event set may include a plurality of events from one of the plurality of design units 110-1 . . . 110-M, or the event set may include various events selected from more than one of the plurality of design units 110-1 . . . 110-M, etc. For example, core processor 110-4 may select several design unit events from the first design unit (e.g., design unit 110-1), which may include several increment events. In this example, the design unit event may include a thread freelist en-queue event, a thread freelist de-queue event, a thread freelist full event, a thread freelist not empty event, etc., as discussed above with reference to FIG. 2. In an embodiment, core processor 110-4 may create an event selection code, based on the design unit number and design event number, for each design unit event to be monitored.

In an embodiment, multiple design unit events may be associated with a single performance event for design units operating at higher clock frequencies than the event timing signal bus (i.e., e.g., data bus 130, control bus 132, etc.). For example, if the internal clock frequency of design unit 110-1 is twice the clock frequency of data bus 130, then two different design unit events may be defined and associated with each higher-frequency, performance event (e.g., an odd clock cycle design unit event and an even clock cycle design unit event). In this example, core processor 110-4 may select both design unit events in order to monitor the performance event at the correct event occurrence frequency. Functional block 112 within design unit 110-1 may include the appropriate hardware, firmware and/or software to provide the signals for each of these two design unit events at the correct frequency. Similar associations may be provided for design units operating at higher internal clock frequencies (e.g., three times, four times, etc.).

A plurality of signals may be selected (510) from a predetermined number of design unit signals. In an embodiment, core processor 110-4 may select a multiplexer number, associated with one of the N design unit event multiplexers, for each design event to be monitored. Core processor 110-4 may send the event selection code and associated multiplexer number to performance monitoring unit 120, which may decode the event selection code and, using the decoded event selection code and multiplexer number, program the appropriate design unit performance monitoring block to output the appropriate design event signal, as discussed above with reference to FIGS. 2, 3 and 4.

A plurality of counters may be associated (520) with the plurality of signals. In an embodiment, core processor 110-4 may select a counter number, associated with one of the plurality of counter blocks 430-1 . . . 430-C, for each design event signal to be monitored. Core processor 110-4 may send the counter number, with the event selection code and multiplexer number, to performance monitoring unit 120, which may program the appropriate event bus multiplexer within the plurality of event bus multiplexers 420-1 . . . 420-Q to route the appropriate design event signal to the appropriate counter block, as discussed above with reference to FIGS. 2, 3 and 4.

For each of the plurality of signals, a number of event occurrences may be counted (530). In an embodiment, each occurrence of each selected design unit event may increment or decrement a counter within one of the plurality of counter blocks 430-1 . . . 430-C within performance monitoring unit 120, as discussed above with reference to FIGS. 2, 3 and 4. For example, an increment event may increment the counter, while a decrement event may decrement the counter. And, for each of the plurality of signals, the number of event occurrences may be sent (540) to a processor unit. In an embodiment, the sampled value of the counter within each of the plurality of counter blocks 430-1 . . . 430-C may be sent (540) from performance monitoring unit 120 to core processor 110-4, for example, in response to a read command received from core processor 110-4, periodically every S seconds, etc., as discussed above with reference to FIGS. 2, 3 and 4.

Several embodiments are specifically illustrated and described herein. However, it will be appreciated that modifications and variations of this disclosure are covered by the above teachings and within the purview of the appended claims without departing from the spirit and intended scope of the present invention.

What is claimed is:

1. A network processor performance monitoring system, comprising:
a core processor;
a plurality of design units, each having a plurality of event multiplexers, coupled to the core processor; and
a performance monitoring unit, coupled to the core processor, including:
a plurality of counter blocks each having a counter,
a plurality of event bus multiplexers coupled to the plurality of counter blocks and the plurality of design unit event multiplexers, and
a control block coupled to the plurality of event bus multiplexers and the plurality of design units.

2. The system of claim 1, wherein the control block includes a state machine and at least one event register.

3. The system of claim 1, further comprising:
a data bus coupled to the core processor and the plurality of design units;
a peripheral bus coupled to the performance monitoring unit and at least one design unit from the plurality of design units;
a control bus coupled to the performance monitoring unit and the plurality of design units; and
a plurality of event buses coupled to the plurality of event bus multiplexers and the plurality of design unit event multiplexers.

4. The system of claim 3, wherein the data bus includes at least two unidirectional data buses.

5. The system of claim 4, wherein the data bus includes an event clocking signal.

6. The system of claim 5, wherein at least four of the plurality of design units operate at different clock frequencies.

7. The system of claim 1, wherein each of the plurality of event bus multiplexers includes one input for each design unit event multiplexer output.

8. The system of claim 7, wherein each design unit event multiplexer includes at least 128 inputs and at least six outputs.

9. The system of claim 1, wherein the plurality of counter blocks includes at least 128 counters.

10. The system of claim 1, wherein each of the plurality of counter blocks includes an up/down counter, a command register, an event register, a status register and a data register.

11. A method for monitoring network processor performance, comprising:
selecting a plurality of events from a predetermined number of design unit events;
selecting a plurality of signals from a predetermined number of design unit signals;
associating a plurality of counters with the plurality of signals; and
for each of the plurality of signals:
counting a number of event occurrences, and
sending the number of event occurrences to a processor unit.

12. The method of claim 11, wherein:
said selecting the plurality of signals includes programming a plurality of design unit event multiplexers; and
associating the plurality of counters includes programming a plurality of event bus multiplexers.

13. The method of claim 12, wherein the predetermined number of design unit events includes at least 128 events.

14. The method of claim 13, wherein the plurality of signals includes at least six signals.

15. The method of claim 14, wherein the predetermined number of design unit signals includes at least six signals from each of a plurality of design units.

16. A network processor performance monitoring apparatus, comprising:
a processor bus interface;
a control bus interface;
a plurality of event bus interfaces;
a plurality of counter blocks, each having a counter, coupled to the processor bus interface;
a plurality of event bus multiplexers coupled to the plurality of counter blocks and the plurality of event bus interfaces; and
a control block coupled to the processor bus interface, the control bus interface and the plurality of event bus multiplexers.

17. The apparatus of claim 16, wherein the control block includes a state machine and at least one event register.

18. The apparatus of claim 16, wherein each of the plurality of event bus multiplexers is coupled to each of the plurality of event bus interfaces and one of the plurality of counter blocks.

19. The apparatus of claim 16, wherein the plurality of event bus interfaces includes at least six event bus interfaces for each of a plurality of design units.

20. The apparatus of claim 16, wherein the plurality of counter blocks includes at least 128 counters.

21. The apparatus of claim 16, wherein each of the plurality of counter blocks includes an up/down counter, a command register, an event register, a status register and a data register.

22. A computer-readable medium storing instructions adapted to be executed by a processor, the instructions comprising:
selecting a plurality of events from a predetermined number of design unit events;
selecting a plurality of signals from a predetermined number of design unit signals;
associating a plurality of counters with the plurality of signals; and
for each of the plurality of signals:
counting a number of event occurrences, and
sending the number of event occurrences to a processor unit.

23. The computer readable medium of claim 22, wherein:
said selecting the plurality of signals includes programming a plurality of design unit event multiplexers; and
associating the plurality of counters includes programming a plurality of event bus multiplexers.

24. The computer readable medium of claim 23, wherein the predetermined number of design unit events includes at least 128 events.

25. The computer readable medium of claim 24, wherein the plurality of signals includes at least six signals.

26. The computer readable medium of claim 25, wherein the predetermined number of design unit signals includes at least six signals from each of a plurality of design units.
